(19) United States
(12) Patent Application Publication
(10) Pub. No.: US 2021/0375651 A1
(43) Pub. Date: Dec. 2, 2021

(54) Fleet Matching Of Semiconductor Metrology Tools Without Dedicated Quality Control Wafers

(71) Applicant: KLA Corporation, Milpitas, CA (US)

(72) Inventors: Song Wu, Shanghai (CN); Tianrong Zhan, Shanghai (CN); Lie-Quan Lee, Fremont, CA (US)

(21) Appl. No.: 17/246,060

(22) Filed: Apr. 30, 2021

Related U.S. Application Data
(60) Provisional application No. 63/030,935, filed on May 28, 2020.

(51) Int. Cl. H01L 21/67; G01N 21/95; G05B 19/418

(52) U.S. Cl. CPC H01L 21/67276; G01N 21/9501; G05B 2219/32368; G01N 2201/127; G01N 2201/126; G05B 19/41875

(57) ABSTRACT

Methods and systems for calibrating metrology tool offset values to match measurement results across a fleet of metrology tools are presented herein. The calibration of offset values is based on measurements of inline, production wafers and does not require the use of specially fabricated and characterized quality control (QC) wafers. In this manner, the entire process flow to calibrate metrology tool offset values is automated and fully integrated within a high volume semiconductor fabrication process flow. In a further aspect, the implementation of a new offset value is regulated by one or more predetermined control limit values. In another further aspect, the measured values of a parameter of interest are adjusted to compensate for the effects of measurement time on the wafer under measurement.

### CROSS REFERENCE TO RELATED APPLICATION

The present application for patent claims priority under 35 U.S.C. § 119 from U.S. provisional patent application Ser. No. 63/030,935, entitled “A Tool-To-Tool Matching Algorithm by using non-Dedicated Quality Control Wafers in a Fleet of Metrology Tools,” filed May 28, 2020, the subject matter of which is incorporated herein by reference in its entirety.

### TECHNICAL FIELD

The described embodiments relate to metrology systems and methods, and more particularly to methods and systems for improved measurement accuracy.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, diffusion, metallization, and ion implantation. Multiple semiconductor devices may be fabricated on a single semiconductor wafer and then separated into individual semiconductor devices.

Accumulated failures at one or more process steps may lead to a reduction of device yield from the semiconductor manufacturing process flow. Metrology processes are used at various steps during a semiconductor manufacturing process to detect defects on wafers to promote higher yield. By way of example, metrology tools measure pattern dimensions, film thicknesses, layer-to-layer alignment, pattern placement, surface topography, electro-optical properties, etc. Metrology techniques offer the potential for high throughput without the risk of sample destruction. A number of optical and x-ray metrology based techniques including scatterometry and reflectometry implementations and associated analysis algorithms are commonly used to characterize critical dimensions, film thicknesses, composition and other parameters of nanoscale structures.

The performance, integration, and reliability of semiconductor devices have continuously improved over time due to enhanced process resolution and increasingly complex device structures. Increased process resolution enables a reduction in the minimum critical size of fabricated structures. Process resolution is primarily driven by the wavelength of the light source employed in the fabrication process. The latest Extreme Ultraviolet Lithography (EUV) light sources generate wavelengths of 13.5 nanometers; enabling fabrication of structural features smaller than 32 nanometers. In addition, more complex device structures, such as FinFET structures and vertical NAND structures, have been developed to improve overall performance, energy cost, integration level, and reliability.

As devices (e.g., logic and memory devices) move toward smaller nanometer-scale dimensions, characterization becomes more difficult. Devices incorporating complex three-dimensional geometry and materials with diverse physical properties contribute to characterization difficulty. In general, metrology systems are required to measure devices at more process steps and with higher precision.

In addition to accurate device characterization, measurement consistency across a range of measurement applications and a fleet of metrology systems tasked with the same measurement objective is also important. If measurement consistency degrades in a manufacturing environment, consistency among processed semiconductor wafers is lost and yield drops to unacceptable levels. Matching measurement results across applications and across multiple systems (i.e., tool-to-tool matching) ensures that measurement results on the same wafer for the same application yield the same result.

Systematic errors exist in each metrology tool of a fleet of metrology tools even though the hardware configuration of each metrology tool in the fleet is well calibrated. These systematic errors result in an offset in measurement results among different tools in the fleet. An offset value assigned to each metrology tool is added to the measurement results associated with each tool to compensate for these systematic errors. After this adjustment, measurement results monitored in a statistical process control (SPC) system are consistent across the fleet of metrology tools. In this manner, any deviation of the fabrication process is detected based on a SPC chart.

A statistical process control monitor of the expected device yield is required across a fleet of metrology tools measuring wafers at the same process step. An offset associated with each metrology tool is introduced to compensate for systemic differences among the fleet of metrology tools. Absent offset compensation, the measurement of a quality control (QC) wafer by a metrology tool is offset or shifted from the measurement of the same QC wafer by another, otherwise identical metrology tool.

Conventionally, the offset associated with each metrology tool is compensated by adding an offset calibration value to the reported measurement value for each tool. Traditionally, the offset calibration value associated with each tool is determined from QC measurements of a set of dedicated QC wafers measured by each of the metrology tools of the fleet. The offset calibration value for each tool is evaluated based on the raw measurement data. By minimizing the effect of tool mismatch, process variations captured by measurements performed by the fleet of metrology tools is effectively magnified.

In some examples, a calibration procedure for a specific process step and a fleet of metrology tools having nominally identical hardware and software configurations is employed to calculate the offset calibration value for each tool.

In this example, a QC wafer is fabricated under process of record (POR) conditions at a particular process step. The QC wafer is then measured by all of the metrology tools of the fleet of metrology tools. For example, if the measurement is a critical dimension (CD) measurement, a CD measurement is obtained from each tool of the set of n tools in the fleet of metrology tools (CD1, CD2, CD3, . . . , CDn). An average value, m, of the measured CD values is determined, where m is the mean or median value of the measured CD values. The offset associated with each tool is determined as the difference between the measured CD value associated with each tool and the average value. For example, for the ith tool, the offset Δi=m−CDᵢ. Finally, the offset value associated with each tool is employed to adjust the reported measurement value from the corresponding tool. For example, Δi, is employed to adjust the reported CD measurement values from the i^{th} tool, CDᵢ*, where CDᵢ*=CDᵢ+Δi*R, where R is a scaling value having a value selected by a user between zero and one.

The aforementioned calibration procedure to determine offset calibration values is repeated as operating conditions change, e.g., process change, metrology tool preventative maintenance, tool repair, scheduled update of tool offsets, etc.

Unfortunately, the traditional approach to calibration of metrology tool offset values to match measurement results across a fleet of metrology tools is time consuming and costly. For example, the production, characterization, and maintenance of QC wafers is very expensive in a high volume production environment. QC wafers must be safely guarded and transported to each tool, and manually loaded and unloaded at each tool. The cost and risk of damage are multiplied when the fleet of metrology tools includes tools in different, distally located facilities. These time and cost constraints limit the achievement of tool-to-tool matching, particularly across fabrication plants where the additional time and risk involved in the transportation of QC wafers is paramount.

As metrology systems have evolved to measure devices at more process steps and with higher precision, so has the complexity of the tool offset calibration process. Improved methods and tools to reduce the time and cost associated with the calibration of metrology tool offset values to match measurement results across a fleet of metrology tools are desired.

### SUMMARY

Methods and systems for calibrating metrology tool offset values to match measurement results across a fleet of metrology tools are presented herein. In particular, the calibration of offset values described herein is based on measurements of inline, production wafers and does not require the use of specially fabricated and characterized quality control (QC) wafers. By eliminating the use of dedicated QC wafers the operational constraints and cost of maintaining tool-to-tool matching in a semiconductor manufacturing setting is dramatically reduced, particularly when tool-to-tool matching is required between different fabrication plants.

Furthermore, the entire process flow to calibrate metrology tool offset values is automated and fully integrated with the high volume semiconductor fabrication process flow. This enables seamless updating of metrology tool offset values without manual intervention and interruption of the process flow. Consequently, tool-to-tool matching of metrology tools is automatically maintained at low operational cost by eliminating the requirement of dedicated quality control wafers and reducing the utilization of human operators.

In a further aspect, the implementation of a new offset value is regulated by one or more predetermined control limit values. In some embodiments, the one or more predetermined control limit values are determined by a user.

In another further aspect, the measured values of the parameter of interest are adjusted to compensate for the effects of measurement time on the wafer under measurement.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a diagram illustrative of a system 100 for measuring characteristics of a semiconductor wafer in accordance with the methods described herein.

FIG. 2 is a diagram illustrative of a fleet of metrology tools 151-154 undergoing calibration of offset values in accordance with the methods described herein.

FIG. 3A is a plot 180 illustrative of the measured parameter values by four different tools over a period of 30 days before any offset correction is applied.

FIG. 3B is a plot 181 illustrative of the offset parameter value implemented daily on each of the four different tools over the period of 30 days.

FIG. 3C is a plot 182 illustrative of the measured parameter values by the four different tools over the period of 30 days after the offset value correction is applied.

FIG. 3D is a plot 183 illustrative of the standard deviation of the uncorrected, measured parameter values and the corrected, measured parameter values across the four different tools over the period of 30 day.

FIG. 4 illustrates a method 200 for calibration of offset values for fleet matching in at least one novel aspect.

### DETAILED DESCRIPTION

Reference will now be made in detail to background examples and some embodiments of the invention, examples of which are illustrated in the accompanying drawings.

In a high volume semiconductor manufacturing setting, a fleet of nominally identical metrology tools is employed to perform measurements of structural and material characteristics (e.g., material composition, dimensional characteristics of structures and films, etc.) at a particular step of a semiconductor fabrication process flow. Calibration of offset values associated with each metrology tool ensures that measurement results from each metrology tool are comparable across the fleet. In other words, if a particular production wafer is measured by two different metrology tools within the fleet, the measurement results should be very close to the same value and free from systematic errors associated with any particular tool.

Methods and systems for calibrating metrology tool offset values to match measurement results across a fleet of metrology tools are presented herein. In particular, the methods and systems for calibrating metrology tool offset values described herein employ inline production wafers and do not require the use of specially fabricated and characterized quality control (QC) wafers. By eliminating the use of dedicated QC wafers the operational constraints and cost of maintaining tool-to-tool matching in a semiconductor manufacturing setting is dramatically reduced, particularly when tool-to-tool matching is required between different fabrication plants.

The use of inline production wafers to calibrate metrology tool offset values allows for a high degree of flexibility in wafer selection and measurement sequence because the calibration data is derived from measurements of inline production wafers, rather than inserting dedicated QC wafers into the production flow. For example, calibration of metrology tool offset values may be based on a significantly larger set of wafers when the calibration is based on measurements of inline production wafers.

Furthermore, the entire process flow to calibrate metrology tool offset values is automated and fully integrated with the high volume semiconductor fabrication process flow. This enables seamless updating of metrology tool offset values without manual intervention and interruption of the high volume semiconductor fabrication process flow.

In this manner, tool-to-tool matching of metrology tools is automatically maintained at low operational cost by eliminating the requirement of dedicated quality control wafers and reducing the utilization of human operators.

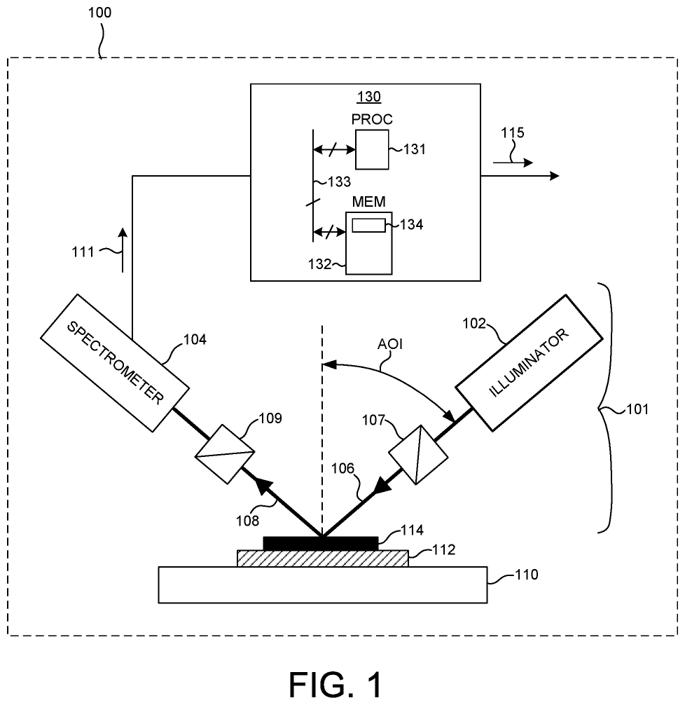

FIG. 1 illustrates a system 100 for measuring characteristics of a semiconductor wafer, e.g., critical dimensions (CDs), thin film thicknesses, optical properties and material compositions, overlay, lithography focus/dose, etc. As shown in FIG. 1, the system 100 may be used to perform spectroscopic ellipsometry measurements of one or more structures 114 of a semiconductor wafer 112 disposed on a wafer positioning system 110. In this aspect, the system 100 may include a spectroscopic ellipsometer 101 equipped with an illuminator 102 and a spectrometer 104. The illuminator 102 of the system 100 is configured to generate and direct illumination of a selected wavelength range to the structure 114 disposed on the surface of the semiconductor wafer 112. In turn, the spectrometer 104 is configured to receive light from the surface of the semiconductor wafer 112. It is further noted that the light emerging from the illuminator 102 is polarized using a polarization state generator 107 to produce a polarized illumination beam 106. The radiation reflected by the structure 114 disposed on the wafer 112 is passed through a polarization state analyzer 109 and to the spectrometer 104. The radiation received by the spectrometer 104 in the collection beam 108 is analyzed with regard to polarization state, allowing for spectral analysis of radiation passed by the analyzer. These spectra 111 are passed to the computing system 130 for analysis of the structure 114.

In a further embodiment, measurement system 100 includes one or more computing systems 130 configured to execute an automated measurement tool to estimate a value 115 of a parameter of interest associated with the one or more structures 114 under measurement. In the preferred embodiment, the measurement tool is a set of program instructions 134 stored in a memory (e.g., memory 132 or an external memory). The program instructions 134 are read and executed by one or more processors 131 of computing system 130 to estimate the value of the parameter of interest. Computing system 130 may be communicatively coupled to the spectrometer 104. In one aspect, computing system 130 is configured to receive measurement data 111 associated with a measurement (e.g., critical dimension, film thickness, composition, process, etc.) of the structure 114 of specimen 112. In one example, the measurement data 111 includes an indication of the measured spectral response of the specimen by measurement system 100 based on the one or more sampling processes from the spectrometer 104. In some embodiments, computing system 130 is further configured to determine specimen parameter values 115 of structure 114 from measurement data 111. In one example, the computing system 130 is configured to access one or more measurement libraries of pre-computed models for determining a value of at least one specimen parameter value associated with the target structure 114. In some examples, the measurement libraries are stored in memory 132.

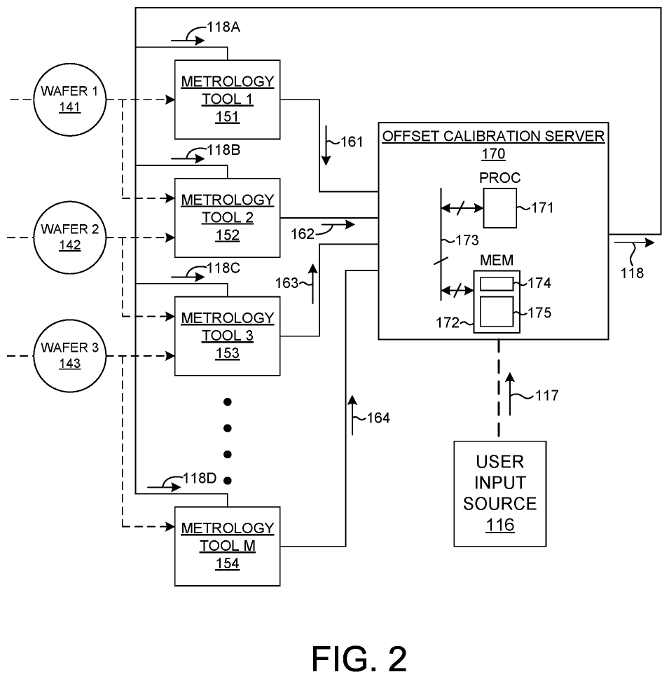

FIG. 2 depicts an illustration of a fleet of metrology tools 151-154 undergoing calibration of offset values in accordance with the methods described herein. As depicted in FIG. 2, metrology tools 151-154 are a fleet of metrology tools tasked with measuring the same structures fabricated on different wafers using the same series of process steps in a production environment. Wafers 141-143 are wafers having undergone the same series of processing steps and are presented to metrology tools 151-154, respectively, at the same process step.

As depicted in FIG. 2, wafers 141-143 are measured by multiple metrology tools of the set of metrology tools 151-154. Estimated values of parameters of interest 161-164 are generated by metrology tools 151-154, respectively. The measured values 161-164 are communicated to offset calibration server 170.

Offset calibration server 170 includes one or more computing systems configured to execute an offset calibration tool to estimate offset values 118 communicated to each of the metrology tools 151-154. In the preferred embodiment, the offset calibration tool is a set of program instructions 174 stored in a memory (e.g., memory 172 or an external memory). The program instructions 174 are read and executed by one or more processors 171 of computing system 130 to estimate offset values. Offset calibration server 170 may be communicatively coupled to metrology tools 151-154. In one aspect, offset calibration server 170 is configured to receive measurement data 161-164 associated with a measurement of a parameter of interest (e.g., critical dimension, film thickness, composition, process, etc.) of one or more structures disposed on wafers 141-143, respectively. In one example, the measurement data 161-164 include an indication of a measured critical dimension of a structure disposed on wafers 141-143, respectively.

In the embodiment depicted in FIG. 2, records of measurements performed by each of the fleet of metrology tools are stored in a data host, e.g., memory 175, which is accessible from the offset calibration server 170. A measurement record includes measurement recipe information, metrology tool information, wafer lot information, wafer information, measurement time, measured parameter value with current offset applied, and the current offset value for each tool. Equation (1) illustrates a set of current offset values, each value corresponding to a different metrology tool of the fleet of M metrology tools

{Δ₁,Δ₂,Δ₃, . . . Δₘ} (1)

As depicted in FIG. 2, offset calibration task configuration information 117 is received from a user input source 116 onto offset calibration server 170. In one example, the user input source 116 is a user interacting with peripheral devices such as a mouse, keyboard, touchscreen, etc. to enter offset calibration task configuration information via a graphical user interface (GUI). The offset calibration task configuration information 117 defines the offset calibration task parameters required to implement a calibration of offset values. By way of non-limiting example, the offset calibration task configuration information 117 includes measurement recipe information, measurement parameters to match, control limits for measurement parameters, measurement time frame, etc. In one example, the measurement time frame is defined by a measurement start time and a measurement end time, typically defined with resolution of at least one second.

Measurement records meeting the task requirements defined by offset calibration task configuration information 117 are loaded from each of the metrology tools or memory 175. In some examples, the measurement records are reviewed against a set of predefined mandatory criteria to verify their validity. In some examples, the criteria are defined in the offset calibration task configuration information 117. By way of non-limiting example, the validity criteria include the goodness of the measurement, measurement status (e.g., normal vs. abnormal measurement), and data within the measurement time frame.

After the appropriate measurement data is loaded onto offset calibration server 170, the measurement records are organized into two parts: 1) measured values of the parameter of interest, and 2) values of the current offset associated with each parameter. The measured values are grouped by wafers. For each wafer, the measurement time and measurement values from one or more metrology tools are included.

As depicted in FIG. 2, offset calibration server 170 determines a bias value for each metrology tool with respect to the average over all the metrology tools. It is not required to run each wafer through all the metrology tools of the fleet to be matched. In general, each wafer of the set of wafers employed to generate measurement data for purposes of fleet matching as presented herein is measured by two or more different metrology tools among the fleet to be matched. Furthermore, the each metrology tool of the fleet to be matched should measure at least one wafer of the set of wafers employed to generate measurement data for purposes of fleet matching as presented herein.

In one example, a fleet of five metrology tools are to be matched. A first wafer is measured on metrology tools #1, #2, and #4 of the fleet of five metrology tools. The bias associated with each of these tools is determined by offset calibration server 170 in accordance with equation (2),

δ₁₁=p̅−p₁₁

δ₂₁=p̅−p₂₁

δ₄₁=p̅−p₄₁ (2)

where, pₘₙ is the value of the measured parameter of interest from the n-th wafer as measured by the m-th tool, p̅ is the average of p₁₁, p₂₁, and p₄₁, and δₘₙ is the bias associated with the m-th tool and n-th wafer. In this example, the average is determined as the mean value or the median value.

In addition, offset calibration server 170 determines an average of the bias for each metrology tool of the fleet to be matched across all of the wafers measured by each of the metrology tools. The average bias is determined by offset calibration server 170 in accordance with equation (3),

δ̅ₘ=average(δₘ₁,δₘ₂,δₘ₃, . . . δₘₙ) (3)

where, δ̅ₘ is the average bias for m-th tool.

For m tools, the average bias associated with each metrology tool of the fleet of metrology tools to be matched is illustrated by equation (4).

{δ̅₁,δ̅₂,δ̅₃, . . . δ̅ₘ} (4)

Offset calibration server 170 determines a new offset value based on the average bias associated with each metrology tool in accordance with equation (5),

Δₘ′=Δₘ+r*δ̅ₘ (5)

where, Δₘ′ is the new offset value associated with the parameter of interest measured by the m-th tool; and r is a scaling ratio having a positive value of one or less. The value of scaling ratio, r, is selected by a user as part of the configuration information 117 to moderate the changes made to the offset value due to the offset calibration process. For m tools, the new offset value associated with each metrology tool of the fleet of metrology tools to be matched is illustrated by equation (6).

{Δ₁′,Δ₂′Δ₃′, . . . Δₘ′} (6)

As depicted in FIG. 2, the updated offset values 118 for all the tools are communicated from offset calibration server 170 to metrology tools 151-154. As illustrated new offset value 118A (Δ₁′) is communicated to metrology tool 151, new offset value 118B (Δ₂′) is communicated to metrology tool 152, new offset value 118C (Δ₃′) is communicated to metrology tool 153, and new offset value 118D (Δₘ′) is communicated to metrology tool 154. In some other embodiments, the new offset values are stored in memory (e.g., memory 175).

In a further aspect, the implementation of a new offset value is regulated by one or more predetermined control limit values. In some embodiments, the one or more predetermined control limit values are determined by a user as part of offset calibration task configuration information 117.

In some embodiments, average bias associated with each metrology tool is compared to one or more predetermined threshold values to determine whether the average bias is within a range of values. If the average bias value exceeds an upper bound predetermined threshold value, the average bias is limited to the upper bound predetermined value, or set to zero. In addition, if the average bias value is less than a lower bound predetermined threshold value, the average bias is limited to the lower bound predetermined value, or set to zero.

In some embodiments, the new offset value is compared to one or more predetermined threshold values to determine whether the new offset value is within a range of values. If the new offset value exceeds an upper bound predetermined threshold value, the new offset value is limited to the upper bound predetermined value, or set to zero. In addition, if the new offset value is less than a lower bound predetermined threshold value, the new offset value is limited to the lower bound predetermined value, or set to zero.

In another further aspect, the measured values of the parameter of interest are adjusted to compensate for measurement time.

In some examples, the measured values characterizing structures fabricated on a wafer drift as a function of time, measurement time, or both. For example, Airborne Molecular Contamination (AMC) is a time dependent accumulation of contaminants that shifts measurement values. In another example, the power and duration of incident radiation employed to perform a measurement induces material changes on the wafer that shift measurement values as a function of measurement time. As result, the value of a parameter of interest determined from measurements of a particular structure trends upward or downward as a function of time or measurement time.

The magnitude of measurement error induced by time dependent or measurement time dependent phenomena is exacerbated by the use of dedicated QC wafers due to the fact that QC wafers are employed for relatively long periods of time and subjected to significantly more measurement time compared to inline, production wafers as described herein. Thus, there is a risk that QC wafers may not represent current production wafers after significant time has elapsed.

Although the risk of time dependent or measurement time dependent measurement drift is significantly reduced by using inline, production wafers, additional steps are described to adjust the measured values of a parameter of interest to compensate for measurement time.

In one example, at least one wafer is measured by the same metrology tool at two different times. For each measurement, the time the measurement is performed is saved in memory (e.g., memory 175). The additional measurement of a wafer on the same tool at different times enables the calculation of the trend in value of the measured parameter as a function of time elapsed between measurements. In this manner, the trending effect due to airborne molecular contamination, for example, may be compensated. In some embodiments, the trend behavior is assumed to be a linear function of time. In these embodiments, the difference in value of the measured parameter divided by the difference in time between measurements quantifies the trend as illustrated in equation (7),

$$k = \frac{{p}_{1}^{′} - {p}_{1}}{{T}_{1}^{′} - {T}_{1}} \qquad ( 7 )$$

where k is the slope of the trending measurement parameter, p₁, is the value of the measured parameter at the first measurement by a first metrology tool, T₁, is the time of the first measurement by the first metrology tool, p₁′, is the value of the measured parameter at the subsequent measurement by the first metrology tool, and T₁′ is the time of the subsequent measurement by the first metrology tool.

In one example, the de-trended value of the measured parameter by any other metrology tool of the fleet of metrology tools is determined in accordance with equation (8),

pₓ′=pₓ−k(Tₓ−T₁) (8)

where pₓ is the value of the measured parameter as measured by the x-th metrology tool, Tₓ is the time of the measurement by the x-th metrology tool, and pₓ′ is the value of the detrended measured parameter value associated with the measurement of parameter by the x-th tool.

In general, the measured parameter value associated with every measurement of this wafer may be detrended as described hereinbefore. For example, a set of detrended measurements of a particular wafer by m metrology tools of a fleet of metrology tools can be expressed by equation (9).

{p₁′,p₂′,p₃′, . . . pₘ′} (9)

By detrending measurement data in the manner described herein, the influence on measurement mismatch caused by wafer trending is diminished significantly. In some examples, offset calibration server 170 determines a bias value for each metrology tool with respect to the average over all the metrology tools as described with reference to equation (2) using detrended measurement data determined in accordance with equation (8).

In some embodiments, time as described with reference to equations (7) and (8) is replaced by measurement count in a sequence of measurements performed on the wafer. In this manner, the trending effect due to radiation dosage, for example, which scales as a function of the number of times the wafer is measured, may be compensated.

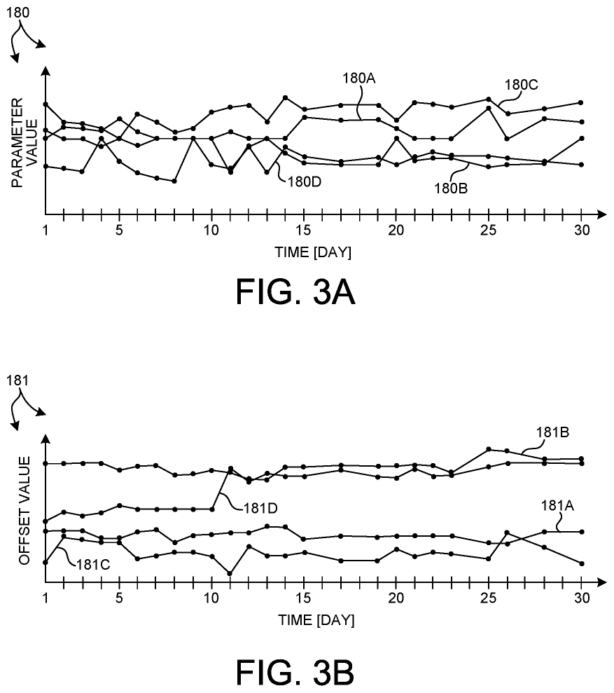

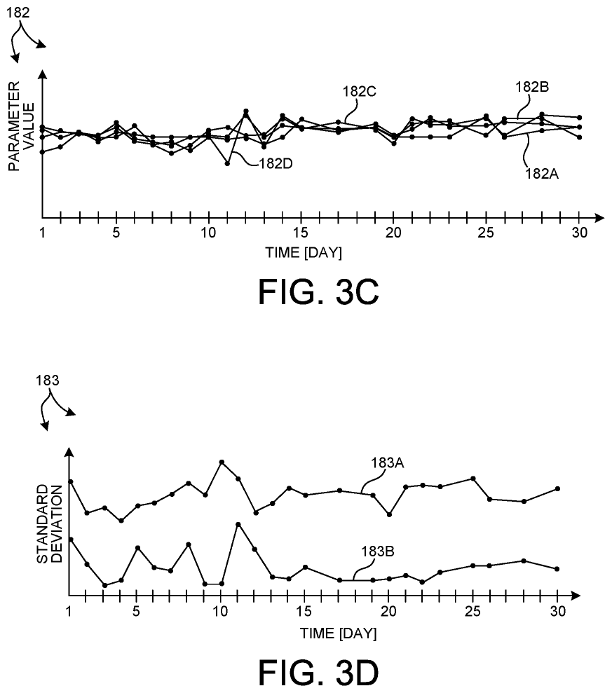

An exemplary calibration of offset parameter values across a fleet of metrology tools is illustrated with reference to FIGS. 3A-3D. A fleet of four optical critical dimension (OCD) metrology tools are implemented in a production environment. The fleet of metrology tools measure wafers at the same production step of a fabrication process flow. More specifically, each in-line production wafer is measured by one of the four metrology tools of the fleet. Each day an inline, production wafer was selected and measured by two or more metrology tools of the fleet of metrology tools for purposes of tool matching as described herein. In this manner, an offset parameter value associated with each of the tools employed to measure the selected wafer on a given day were updated that day, while the tools not employed to measure the selected wafer on the given day were not updated that day. To ensure that each tool in the fleet was updated periodically, the two or more tools selected to measure a selected wafer on a given day were rotated among the fleet.

FIG. 3A is a plot 180 illustrative of the measured parameter values by four different tools over a period of 30 days before any offset correction is applied. Plotline 180A depicts the measurement results of tool #1, plotline 180B depicts the measurement results of tool #2, plotline 180C depicts the measurement results of tool #3, and plotline 180D depicts the measurement results of tool #4. As illustrated in FIG. 3A, the wafers measured by each tool are different, and the wafers measured each day by each tool are different. Thus, the uncorrected, measured values exhibit differences across tools and over time (e.g., day-to-day) due to both systematic tool differences and differences in actual dimensions on the measured wafers.

FIG. 3B is a plot 181 illustrative of the offset parameter value implemented daily on each of tools #1-4 over the period of 30 days. Plotline 181A depicts the offset parameter values implemented on tool #1, plotline 181B depicts the offset parameter values implemented on tool #2, plotline 181C d depicts the offset parameter values implemented on tool #3, and plotline 181D depicts the offset parameter values implemented on tool #4. As depicted in FIG. 3B, occasionally there is a large shift in the offset parameter value implemented on a particular tool. This occurs when a major change, such as a preventative maintenance event is performed on the tool. As illustrated in FIG. 3B, the offset parameter values determined in accordance with the methods described herein are able to compensate for tool changes and maintain tool-to-tool matching.

FIG. 3C is a plot 182 illustrative of the measured parameter values by the four different tools over the period of 30 days after the offset value correction is applied. Plotline 182A depicts the measurement results of tool #1, plotline 182B depicts the measurement results of tool #2, plotline 182C depicts the measurement results of tool #3, and plotline 182D depicts the measurement results of tool #4. As illustrated in FIG. 3C, the wafers measured by each tool are different, and the wafers measured each day by each tool are different. Thus, the corrected, measured values exhibit differences across tools and over time (e.g., day-to-day) due to differences in actual dimensions on the measured wafers, while the influence of systematic tool differences has been significantly reduced.

FIG. 3D is a plot 183 illustrative of the standard deviation of the uncorrected, measured parameter values and the corrected, measured parameter values across the four different tools over the period of 30 day. Plotline 183A depicts the standard deviation of the uncorrected, measured parameter values across the four tools over the 30 day period. Plotline 183B depicts the standard deviation of the corrected, measured parameter values across the four tools over the 30 day period. As illustrated in FIG. 3D, the standard deviation of measured parameter of interest across all tools is reduced by a factor of −3.5 by implementing the offset parameter values determined in accordance with the methods described herein. Thus, the ability to reduce the influence of systematic differences across a fleet of metrology tools on measurement accuracy is clearly illustrated.

It should be recognized that the various steps described throughout the present disclosure may be carried out by a single computer system 170 or, alternatively, a multiple computer system 170. Moreover, different subsystems of the system 100, such as the spectroscopic ellipsometer 101, may include a computer system suitable for carrying out at least a portion of the steps described herein. Therefore, the aforementioned description should not be interpreted as a limitation on the present invention but merely an illustration. Further, computing system 170 may be configured to perform any other step(s) of any of the method embodiments described herein.

The computing system 170 may include, but is not limited to, a personal computer system, mainframe computer system, workstation, image computer, parallel processor, or any other device known in the art. In general, the term “computing system” may be broadly defined to encompass any device having one or more processors, which execute instructions from a memory medium. In general, computing system 170 may be integrated with a measurement system such as measurement system 100, or alternatively, may be separate from any measurement system. In this sense, computing system 170 may be remotely located and receive measurement data and user input 117 from any measurement source and user input source, respectively.

Program instructions 174 implementing methods such as those described herein may be transmitted over a transmission medium such as a wire, cable, or wireless transmission link. Memory 172 storing program instructions 174 may include a computer-readable medium such as a read-only memory, a random access memory, a magnetic or optical disk, or a magnetic tape.

In addition, the computer system 170 may be communicatively coupled to metrology tool, or the user input source 116 in any manner known in the art.

The computing system 170 may be configured to receive and/or acquire data or information from the user input source 116 and subsystems of a metrology system (e.g., spectrometer 104, illuminator 102, and the like) by a transmission medium that may include wireline and/or wireless portions. In this manner, the transmission medium may serve as a data link between the computer system 170, user input source 116, and a metrology system, such as metrology system 100. Further, the computing system 170 may be configured to receive measurement data via a storage medium (i.e., memory). For instance, the spectral results obtained using a spectrometer of ellipsometer 101 may be stored in a permanent or semi-permanent memory device (not shown). In this regard, the spectral results may be imported from an external system. Moreover, the computer system 170 may send data to external systems via a transmission medium.

The embodiments of the offset calibration server 170 illustrated in FIG. 2 may be further configured as described herein. In addition, the server 170 may be configured to perform any other block(s) of any of the method embodiment(s) described herein.

In general, any number of parameters of interest may be selected and provide the basis for offset value calibration. Exemplary parameters of interest include geometric parameters such as a shape parameter such as a critical dimension (CD), sidewall angle (SWA), height (H), etc., composition, film thickness, bandgap, electrical properties, lithography focus, lithography dosage, overlay, and other process parameters (e.g., resist state, partial pressure, temperature, focusing model).

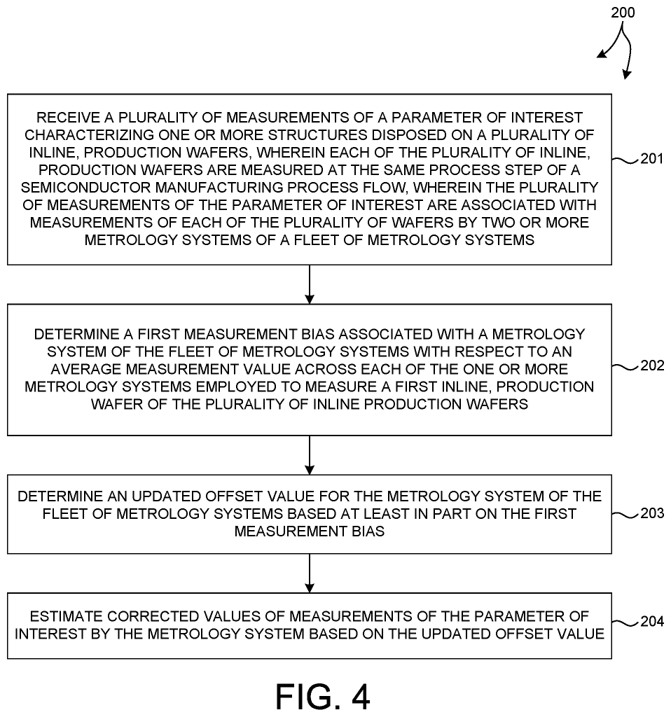

FIG. 4 illustrates a method 200 for calibration of offset values for fleet matching in at least one novel aspect. Method 200 is suitable for implementation by an offset calibration server such as offset calibration server 170 illustrated in FIG. 2 of the present invention. In one aspect, it is recognized that data processing blocks of method 200 may be carried out via a pre-programmed algorithm executed by one or more processors of computing system 170, or any other general purpose computing system. It is recognized herein that the particular structural aspects of system 170 do not represent limitations and should be interpreted as illustrative only.

In block 201, a plurality of measurements of a parameter of interest characterizing one or more structures disposed on a plurality of inline, production wafers are received. Each of the plurality of inline, production wafers are measured at the same process step of a semiconductor manufacturing process flow. The plurality of measurements of the parameter of interest are associated with measurements of each of the plurality of wafers by two or more metrology systems of a fleet of metrology systems.

In block 202, a first measurement bias associated with a metrology system of the fleet of metrology systems is determined with respect to an average measurement value across each of the one or more metrology systems employed to measure a first inline, production wafer of the plurality of inline production wafers.

In block 203, an updated offset value for the metrology system of the fleet of metrology systems is determined based at least in part on the first measurement bias.

In block 204, corrected values of measurements of the parameter of interest by the metrology system are estimated based on the updated offset value.

In an optional block (not shown), the updated offset value is stored in a memory of a computing system (e.g., memory 172 of computing system 170 or an external memory).

Although the methods discussed herein are explained with reference to metrology systems such as metrology system 100, any metrology system configured to illuminate and detect radiation reflected, transmitted, or diffracted from a specimen may be employed to implement the exemplary methods described herein, including optical and x-ray based metrology systems. Exemplary systems include an angle-resolved reflectometer, a scatterometer, a reflectometer, an ellipsometer, a spectroscopic reflectometer or ellipsometer, a beam profile reflectometer, a multi-wavelength, two-dimensional beam profile reflectometer, a multi-wavelength, two-dimensional beam profile ellipsometer, a rotating compensator spectroscopic ellipsometer, etc. By way of non-limiting example, an ellipsometer may include a single rotating compensator, multiple rotating compensators, a rotating polarizer, a rotating analyzer, a modulating element, multiple modulating elements, or no modulating element.

It is noted that the output from a metrology system may be configured in such a way that the metrology system uses more than one technology. In fact, an application may be configured to employ any combination of available metrology sub-systems within a single tool, or across a number of different tools.

A system implementing the methods described herein may also be configured in a number of different ways. For example, a wide range of wavelengths (including visible, ultraviolet, infrared, and X-ray), angles of incidence, states of polarization, and states of coherence may be contemplated. In another example, the system may include any of a number of different light sources (e.g., a directly coupled light source, a laser-sustained plasma light source, etc.). In another example, the system may include elements to condition light directed to or collected from the specimen (e.g., apodizers, filters, etc.).

In the field of semiconductor metrology, a metrology system may comprise an illumination system which illuminates a target, a collection system which captures relevant information provided by the illumination system's interaction (or lack thereof) with a target, device or feature, and a processing system which analyzes the information collected using one or more algorithms. Metrology tools can be used to measure structural and material characteristics (e.g, material composition, dimensional characteristics of structures and films such as film thickness and/or critical dimensions of structures, overlay, etc.) associated with various semiconductor fabrication processes. These measurements are used to facilitate process controls and/or yield efficiencies in the manufacture of semiconductor dies.

A metrology system can comprise one or more hardware configurations which may be used in conjunction with certain embodiments of this invention to, e.g., measure the various aforementioned semiconductor structural and material characteristics. Examples of such hardware configurations include, but are not limited to, the following: a spectroscopic ellipsometer (SE), a SE with multiple angles of illumination, a SE measuring Mueller matrix elements (e.g. using rotating compensator(s)), a single-wavelength ellipsometer, a beam profile ellipsometer (angle-resolved ellipsometer), a beam profile reflectometer (angle-resolved reflectometer), a broadband reflective spectrometer (spectroscopic reflectometer), a single-wavelength reflectometer, an angle-resolved reflectometer, an imaging system, and a scatterometer (e.g. speckle analyzer).

The hardware configurations can be separated into discrete operational systems. On the other hand, one or more hardware configurations can be combined into a single tool. One example of such a combination of multiple hardware configurations into a single tool is described in U.S. Pat. No. 7,933,026, which is hereby incorporated by reference in its entirety for all purposes. In many cases, multiple metrology tools are used for measurements on single or multiple metrology targets. This is described, e.g. in by Zangooie et al., in U.S. Pat. No. 7,478,019, which is hereby incorporated by reference in its entirety for all purposes.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), a displacement between two or more structures (e.g., overlay displacement between overlaying grating structures, etc.), and a dispersion property value of a material used in the structure or part of the structure. Structures may include three dimensional structures, patterned structures, overlay structures, etc.

As described herein, the term “critical dimension application” or “critical dimension measurement application” includes any critical dimension measurement.

As described herein, the term “metrology system” includes any measurement system employed at least in part to characterize a specimen in any aspect, including systems that may be referred to as “inspection” systems. Such terms of art do not limit the scope of the term “metrology system” as described herein. In addition, the metrology system 100 may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the calibration of system parameters based on critical dimension data.

Various embodiments are described herein for a semiconductor processing system (e.g., a metrology system or a lithography system) that may be used for processing a specimen. The term “specimen” is used herein to refer to a site, or sites, on a wafer, a reticle, or any other sample that may be processed (e.g., printed or inspected for defects) by means known in the art. In some examples, the specimen includes a single site having one or more measurement targets whose simultaneous, combined measurement is treated as a single specimen measurement or reference measurement. In some other examples, the specimen is an aggregation of sites where the measurement data associated with the aggregated measurement site is a statistical aggregation of data associated with each of the multiple sites. Moreover, each of these multiple sites may include one or more measurement targets associated with a specimen or reference measurement.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned”. For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO₂. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A method comprising:
receiving a plurality of measurements of a parameter of interest characterizing one or more structures disposed on a plurality of inline, production wafers, wherein each of the plurality of inline, production wafers are measured at the same process step of a semiconductor manufacturing process flow, wherein the plurality of measurements of the parameter of interest are associated with measurements of each of the plurality of wafers by two or more metrology systems of a fleet of metrology systems;
determining a first measurement bias associated with a metrology system of the fleet of metrology systems with respect to an average measurement value across each of the one or more metrology systems employed to measure a first inline, production wafer of the plurality of inline production wafers;
determining an updated offset value for the metrology system of the fleet of metrology systems based at least in part on the first measurement bias; and
estimating corrected values of measurements of the parameter of interest by the metrology system based on the updated offset value.

2. The method of claim 1, further comprising:
determining a second measurement bias associated with the metrology system of the fleet of metrology systems with respect to an average measurement value across each of the two or more metrology systems employed to measure a second inline, production wafer of the plurality of inline production wafers; and
determining an average value of the measurement bias associated with the metrology system based at least in part on the first measurement bias and the second measurement bias, wherein the updated offset value is based on the average value of the measurement bias.

3. The method of claim 2, wherein the average value of the measurement bias is determined as a mean value or a median value.

4. The method of claim 1, wherein the estimating of the corrected values of measurements of the parameter of interest by the metrology system is determined by adding a correction term to the values of measurements of the parameter of interest by the metrology system, wherein the correction term is a product of the updated offset value and a scaling factor.

5. The method of claim 4, wherein the scaling factor has a positive value less than or equal to one.

6. The method of claim 1, further comprising:
adjusting the measured values of the parameter of interest associated with measurements of an inline, production wafer of the plurality of inline production wafers by a first metrology system of the fleet of metrology systems based on a time elapsed between measurements of the inline, production wafer by the first metrology system and a second metrology system of the fleet of metrology systems.

7. The method of claim 1, further comprising:
adjusting the measured values of the parameter of interest associated with measurements of an inline, production wafer of the plurality of inline production wafers by a first metrology system of the fleet of metrology systems based on a duration of time measurements of the inline, production wafer are performed by the first metrology system and a second metrology system of the fleet of metrology systems.

8. The method of claim 1, further comprising:
comparing the updated offset value for the metrology system of the fleet of metrology systems with an upper bound predetermined threshold and a lower bound predetermined threshold value;
substituting the upper bound predetermined threshold value for the updated offset value if the updated offset value exceeds the upper bound predetermined threshold value; and
substituting the lower bound predetermined threshold value for the updated offset value if the updated offset value is less than the lower bound predetermined threshold value.

9. The method of claim 1, further comprising:
determining a difference between the updated offset value for the metrology system of the fleet of metrology systems and a current offset value for the metrology system;
substituting an upper bound predetermined threshold value for the updated offset value if the difference exceeds the upper bound predetermined threshold value; and
substituting a upper bound predetermined threshold value for the updated offset value if the difference is less than the lower bound predetermined threshold value.

10. A system comprising:
a plurality of measurement systems each comprising:
an illumination source configured to provide an amount of illumination radiation to one or more structures disposed on an inline, production wafer;
a detector configured to receive an amount of collected radiation from the one or more structures in response to the amount of illumination radiation and generate measurement signals indicative of the collected radiation; and
one or more computer systems configured to:
receive a plurality of measurements from the plurality of measurement systems, wherein each of the plurality of measurements is a value of a parameter of interest characterizing the one or more structures disposed on each of a plurality of inline, production wafers, wherein each of the plurality of inline, production wafers are measured at the same process step of a semiconductor manufacturing process flow, wherein the plurality of measurements of the parameter of interest are associated with measurements of each of the plurality of inline, production wafers by two or more measurement systems of the plurality of measurement systems;
determine a first measurement bias associated with a measurement system of the plurality of measurement systems with respect to an average measurement value across each of the one or more measurement systems employed to measure a first inline, production wafer of the plurality of inline production wafers;
determine an updated offset value for the measurement system of the plurality of measurement systems based at least in part on the first measurement bias; and
estimate corrected values of measurements of the parameter of interest by the measurement system based on the updated offset value.

11. The system of claim 10, the one or more computing systems further configured to:
determine a second measurement bias associated with the measurement system of the plurality of measurement systems with respect to an average measurement value across each of the two or more measurement systems employed to measure a second inline, production wafer of the plurality of inline, production wafers; and
determine an average value of the measurement bias associated with the measurement system based at least in part on the first measurement bias and the second measurement bias, wherein the updated offset value is based on the average value of the measurement bias.

12. The system of claim 11, wherein the average value of the measurement bias is determined as a mean value or a median value.

13. The system of claim 10, wherein the estimating of the corrected values of measurements of the parameter of interest by the measurement system is determined by adding a correction term to the values of measurements of the parameter of interest by the measurement system, wherein the correction term is a product of the updated offset value and a scaling factor.

14. The system of claim 13, wherein the scaling factor has a positive value less than or equal to one.

15. The system of claim 10, the one or more computing systems further configured to:
adjust the measured values of the parameter of interest associated with measurements of an inline, production wafer of the plurality of inline production wafers by a first measurement system of the plurality of measurement systems based on a time elapsed between measurements of the inline, production wafer by the first measurement system and a second measurement system of the plurality of metrology systems.

16. The system of claim 10, the one or more computing systems further configured to:
adjust the measured values of the parameter of interest associated with measurements of an inline, production wafer of the plurality of inline production wafers by a first measurement system of the plurality of measurement systems based on a duration of time measurements of the inline, production wafer are performed by the first measurement system and a second measurement system of the plurality of measurement systems.

17. The system of claim 10, the computing system further configured to:
compare the updated offset value for the measurement system of the plurality of measurement systems with an upper bound predetermined threshold and a lower bound predetermined threshold value;
substitute the upper bound predetermined threshold value for the updated offset value if the updated offset value exceeds the upper bound predetermined threshold value; and
substitute the lower bound predetermined threshold value for the updated offset value if the updated offset value is less than the lower bound predetermined threshold value.

18. The system of claim 10, the computing system further configured to:
determine a difference between the updated offset value for the measurement system of the plurality of measurement systems and a current offset value for the measurement system;
substitute an upper bound predetermined threshold value for the updated offset value if the difference exceeds the upper bound predetermined threshold value; and
substitute a upper bound predetermined threshold value for the updated offset value if the difference is less than the lower bound predetermined threshold value.

19. An offset calibration tool comprising:
one or more processors of a computing system; and
a non-transitory, computer-readable medium storing computer-readable instructions, the computer-readable instructions, when executed by the one or more processors, cause the computing system to:
receive a plurality of measurements of a parameter of interest characterizing one or more structures disposed on a plurality of inline, production wafers, wherein each of the plurality of inline, production wafers are measured at the same process step of a semiconductor manufacturing process flow, wherein the plurality of measurements of the parameter of interest are associated with measurements of each of the plurality of wafers by two or more metrology systems of a fleet of metrology systems;
determine a first measurement bias associated with a metrology system of the fleet of metrology systems with respect to an average measurement value across each of the one or more metrology systems employed to measure a first inline, production wafer of the plurality of inline production wafers;
determine an updated offset value for the metrology system of the fleet of metrology systems based at least in part on the first measurement bias; and
estimate corrected values of measurements of the parameter of interest by the metrology system based on the updated offset value.

20. The offset calibration tool of claim 19, the computer-readable instructions, when executed by the one or more processors of the computing system, further cause the computing system to:
determine a second measurement bias associated with the metrology system of the fleet of metrology systems with respect to an average measurement value across each of the two or more metrology systems employed to measure a second inline, production wafer of the plurality of inline production wafers; and
determine an average value of the measurement bias associated with the metrology system based at least in part on the first measurement bias and the second measurement bias, wherein the updated offset value is based on the average value of the measurement bias.
